(19) United States
(12) Patent Application Publication
(10) Pub. No.: US 2024/0088859 A1
(43) Pub. Date: Mar. 14, 2024

(54) METHOD FOR MANUFACTURING VIBRATOR

(71) Applicant: SEIKO EPSON CORPORATION, Tokyo (JP)

(72) Inventors: Atsushi Matsuo, Shiojiri-shi (JP); Katsuhiko Maki, Chino-shi (JP)

(21) Appl. No.: 18/457,844

(22) Filed: Aug. 29, 2023

(30) Foreign Application Priority Data
Sep. 1, 2022 (JP) 2022-139032

(51) Int. Cl. H03H 3/02; H03H 9/19

(52) U.S. Cl. CPC H03H 3/02; H03H 9/19

(57) ABSTRACT

A method for manufacturing a vibrator includes: a preparation process of preparing a quartz-crystal wafer including a vibrator and a holding portion, the vibrator including a support portion and a vibration part arranged side by side along a first direction, the holding portion being coupled to one end portion of the support portion in a second direction intersecting the first direction; an adhering process of fixing at least the support portion and the holding portion of the quartz-crystal wafer to a film via an adhesive; and a singulation process of stretching the film along the second direction, and separating and singulating the vibrator from the holding portion.

The present application is based on, and claims priority from JP Application Serial Number 2022-139032, filed Sep. 1, 2022, the disclosure of which is hereby incorporated by reference herein in its entirety.

### BACKGROUND

### 1. Technical Field

The present disclosure relates to a method for manufacturing a vibrator.

### 2. Related Art

JP-A-2010-87842 discloses a method of obtaining a piezoelectric vibrator element from a frame by pressing a protruding portion to a position away from the piezoelectric vibrator element and breaking a coupling portion coupled to the frame.

JP-A-2007-135132 discloses a method in which a plurality of breaking pins provided to respectively face a plurality of piezoelectric elements supported on a wafer are pressed against the piezoelectric elements to simultaneously singulate the plurality of piezoelectric elements from the wafer.

However, in the technique disclosed in JP-A-2010-87842, since the piezoelectric vibrator elements are broken off one by one, there is a problem that the manufacturing time of a piezoelectric element is long. Further, there is a problem that it is difficult to prevent scattering of breaking-off waste generated when the coupling portion is broken.

Further, in the technique disclosed in JP-A-2007-135132, there is a concern that an electrode may be damaged due to contact of the breaking pin with the piezoelectric element, causing deterioration in vibration characteristics of the piezoelectric element. Further, there is a problem that it is difficult to prevent scattering of breaking-off waste generated when breaking-off is performed.

### SUMMARY

A method for manufacturing a vibrator includes: a preparation process of preparing a quartz-crystal wafer including a vibrator and a holding portion, the vibrator including a support portion and a vibration part arranged side by side along a first direction, the holding portion being coupled to one end portion of the support portion in a second direction intersecting the first direction; an adhering process of fixing at least the support portion and the holding portion of the quartz-crystal wafer to a film via an adhesive; and a process of stretching the film along the second direction and separating and singulating the vibrator from the holding portion.

### BRIEF DESCRIPTION OF THE DRAWINGS

FIG. 1 is a plan view illustrating a configuration of a quartz-crystal wafer including a vibrator.

FIG. 2 is a plan view illustrating a configuration of the vibrator.

FIG. 3 is a cross-sectional view taken along a line A-A of the vibrator illustrated in FIG. 2.

FIG. 4 is a flowchart illustrating a method for manufacturing a vibrator.

FIG. 5 is a plan view illustrating a configuration of the quartz-crystal wafer.

FIG. 6 is a cross-sectional view taken along a line B-B of the quartz-crystal wafer illustrated in FIG. 5.

FIG. 7 is a cross-sectional view taken along a line C-C of the quartz-crystal wafer illustrated in FIG. 5.

FIG. 8 is a plan view illustrating a part of the method for manufacturing a vibrator.

FIG. 9 is a plan view illustrating a part of a method for manufacturing a vibrator according to a modification.

FIG. 10 is a plan view illustrating a part of the method for manufacturing a vibrator according to the modification.

FIG. 11 is a plan view illustrating a part of a method for manufacturing a vibrator according to a modification.

FIG. 12 is a plan view illustrating a part of the method for manufacturing a vibrator according to the modification.

FIG. 13 is a plan view illustrating a part of a method for manufacturing a vibrator according to a modification.

FIG. 14 is a plan view illustrating a part of the method for manufacturing a vibrator according to the modification.

FIG. 15 is a plan view illustrating a part of a method for manufacturing a vibrator according to a modification.

FIG. 16 is a plan view illustrating a part of the method for manufacturing a vibrator according to the modification.

FIG. 17 is a plan view illustrating a part of a method for manufacturing a vibrator according to a modification.

FIG. 18 is a plan view illustrating a part of the method for manufacturing a vibrator according to the modification.

### DESCRIPTION OF EMBODIMENTS

In the following drawings, three axes orthogonal to one another will be described as an X axis, a Y axis, and a Z axis. A direction along the X axis is defined as an “X direction”, a direction along the Y axis is defined as a “Y direction”, and a direction along the Z axis is defined as a “Z direction”. A direction indicated by an arrow is defined as a + direction, and a direction opposite to the + direction is defined as a −direction. A+Z direction may be referred to as “upper” or “upper side”, a −Z direction may be referred to as “lower” or “lower side”, and a view from the +Z direction and the −Z direction is also referred to as a plan view or planar view. A surface on a +Z direction side is described as an upper surface and a surface on a −Z direction side opposite to the +Z direction side is described as a lower surface. The Y direction is also referred to as a first direction, and the X direction is also referred to as a second direction.

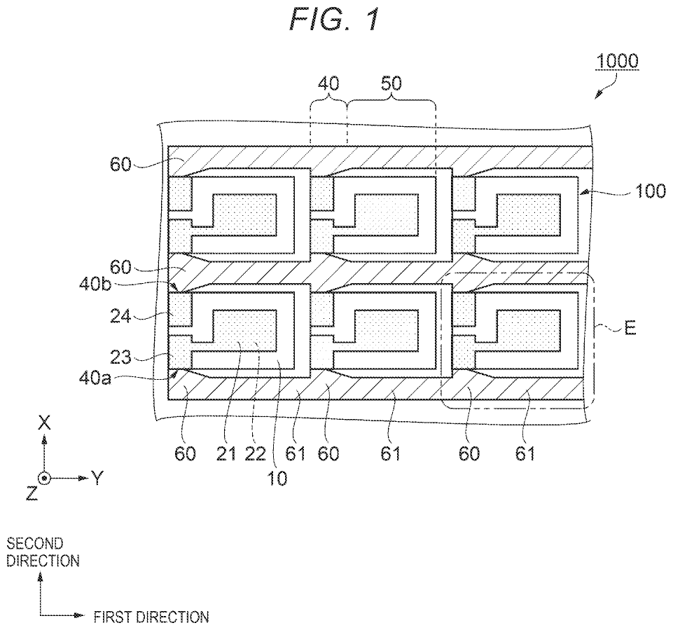

First, a configuration of a quartz-crystal wafer 1000 including a plurality of vibrators 100 will be described with reference to FIG. 1.

The quartz-crystal wafer 1000 illustrated in FIG. 1 is in a state in which the plurality of vibrators 100 are coupled to a quartz-crystal substrate, in other words, in a state before the vibrator 100 is singulated. The quartz-crystal wafer 1000 includes the vibrator 100, which includes a support portion 40 and a vibration part 50 arranged side by side along the first direction, and holding portions 60 coupled to end portions 40a and 40b of the support portion 40 in the second direction intersecting the first direction.

The quartz-crystal wafer 1000 includes a plurality of vibrators 100 arranged side by side along the first direction and a plurality of vibrators 100 arranged side by side along the second direction. The holding portion 60 is coupled to the end portions 40a and 40b of each of the vibrators 100. The holding portions 60 adjacent to each other in the first direction are coupled to each other by a first coupling portion 61.

Further, the quartz-crystal wafer 1000 includes the plurality of holding portions 60 coupled by the first coupling portion 61, and the plurality of vibrators 100 arranged side by side along the first direction. The plurality of holding portions 60 coupled by the first coupling portion 61 and the plurality of vibrators 100 arranged side by side in the first direction are alternately arranged in the second direction. That is, the vibrator 100 is coupled to the holding portion 60 at one end portion 40a of the support portion 40 in the second direction, and is coupled to another holding portion 60 at the other end portion 40b of the support portion 40 in the second direction.

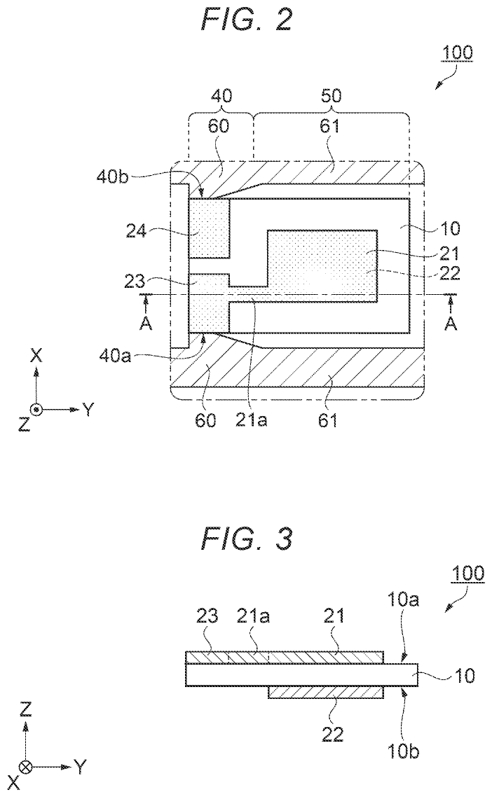

Next, the configuration of the vibrator 100 will be described with reference to FIGS. 2 and 3.

As illustrated in FIGS. 2 and 3, the vibrator 100 includes a vibrator element 10, a first excitation electrode 21, a second excitation electrode 22, a first support electrode 23, and a second support electrode 24.

The vibrator element 10 is made of various piezoelectric materials, such as a quartz-crystal element. The vibrator element 10 is, for example, an AT-cut quartz-crystal element. In the embodiment, the vibrator element 10 is an AT-cut quartz-crystal element having a square planar shape, specifically, a rectangular shape. Therefore, the + directions of the X axis, the Y axis, and the Z axis in the drawings correspond to + directions of a Z′ axis, an X axis, and a Y′ axis of crystal axes of the quartz crystal, respectively. The present disclosure is not necessarily limited to this, and at least one of the axes may correspond to the −direction.

The vibrator element 10 includes the vibration part 50, the support portion 40 disposed away from the vibration part 50, and a coupling wiring 21a that couples the vibration part 50 and the support portion 40.

The first excitation electrode 21 is provided substantially at a center of a first principal surface 10a of the vibrator element 10. The second excitation electrode 22 is provided substantially at a center of a second principal surface 10b, which has a front and back relationship with the first principal surface 10a of the vibrator element 10, so as to overlap the first excitation electrode 21 in a plan view.

The first excitation electrode 21 is electrically coupled to the first support electrode 23 via the coupling wiring 21a. The second excitation electrode 22 is electrically coupled to the second support electrode 24 via a coupling wiring (not illustrated). The second support electrode 24 is electrically coupled to a coupling wiring (not illustrated) via, for example, a through electrode provided in a manner of passing through the vibrator element 10.

That is, the first support electrode 23 is provided at the support portion 40 and electrically coupled to the first excitation electrode 21. The second support electrode 24 is provided at the support portion 40 and electrically coupled to the second excitation electrode 22.

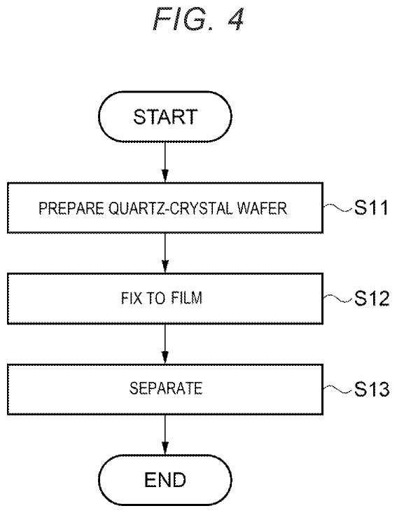

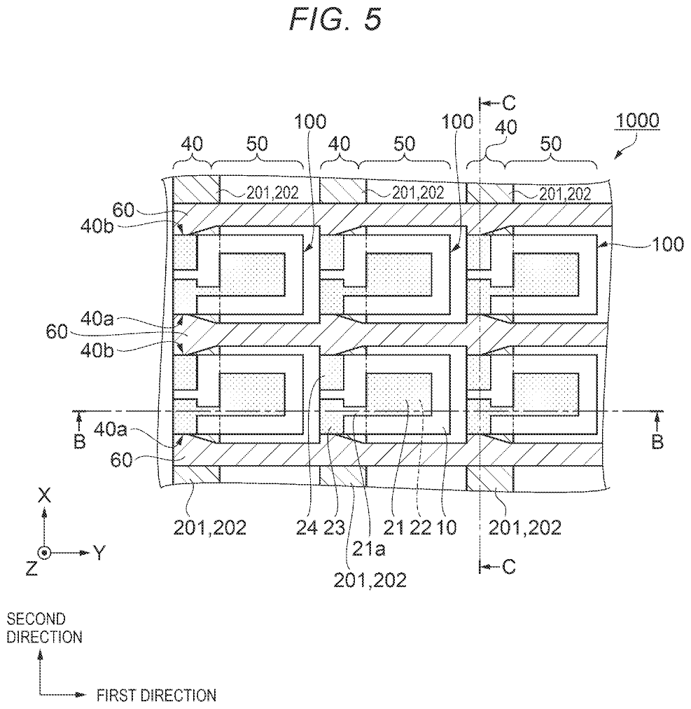

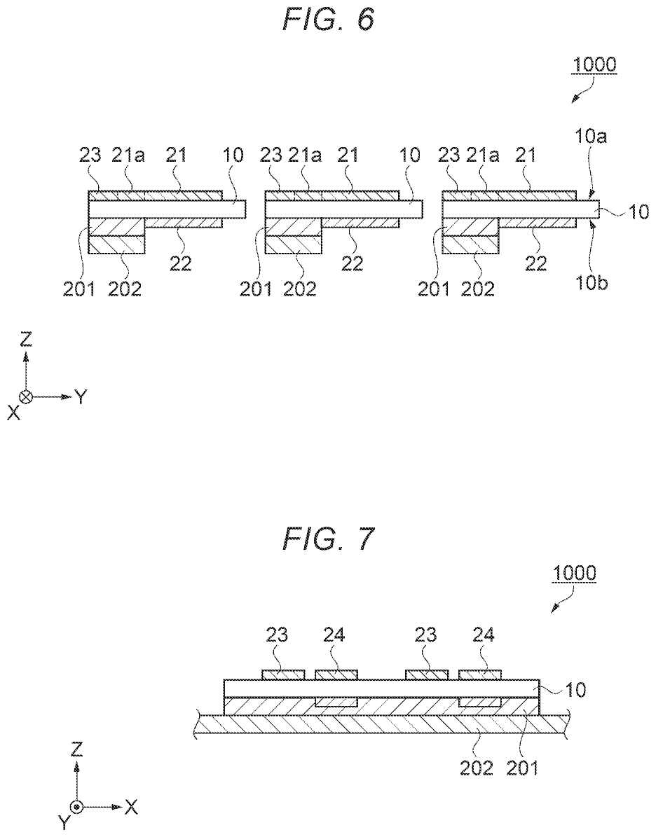

Next, a method for manufacturing the vibrator 100 will be described with reference to FIGS. 4 to 8. FIG. 6 is a cross-sectional view taken along a line B-B of the quartz-crystal wafer 1000 illustrated in FIG. 5. FIG. 7 is a cross-sectional view taken along a line C-C of the quartz-crystal wafer 1000 illustrated in FIG. 5.

First, as illustrated in FIG. 4, in step S11 (preparation process), the quartz-crystal wafer 1000 is prepared. As illustrated in FIG. 5, the quartz-crystal wafer 1000 has the same configuration as that of the quartz-crystal wafer 1000 illustrated in FIG. 1.

The quartz-crystal wafer 1000 includes the vibrator 100, which includes the support portion 40 and the vibration part 50 that are arranged side by side along the first direction, and the holding portion 60 coupled to one end portion 40a and the other end portion 40b of the support portion 40 in the second direction intersecting the first direction. The quartz-crystal wafer 1000 has the plurality of vibrators 100 arranged in the first direction and the second direction.

In addition, as illustrated in FIG. 6, the quartz-crystal wafer 1000 is in a state in which an external shape is hollowed out in a shape of the vibrator 100 by, for example, a photolithography technique and an etching technique. The first excitation electrode 21 is provided at the first principal surface 10a of the vibrator element 10. The second excitation electrode 22 is provided at the second principal surface 10b of the vibrator element 10.

The quartz-crystal wafer 1000 includes a plurality of holding portions 60 coupled by the first coupling portion 61, and a plurality of vibrators 100 arranged side by side along the first direction. The plurality of holding portions 60 coupled by the first coupling portion 61 and the plurality of vibrators 100 arranged side by side in the first direction are alternately arranged in the second direction.

In step S12 (adhering process), at least the support portion 40 and the holding portion 60 of the quartz-crystal wafer 1000 are fixed to a film 202 via an adhesive 201.

Specifically, as illustrated in FIGS. 5 to 7, the film 202 is fixed, via the adhesive 201, to a region of the second principal surface 10b overlapping the support portion 40. Examples of the adhesive 201 include a rubber-based adhesive, an acrylic-based adhesive, a urethane-based adhesive, and a silicone-based adhesive. Examples of the film 202 include a plastic film.

In step S13 (singulation process), a plurality of vibrators 100 are simultaneously singulated from the quartz-crystal wafer 1000.

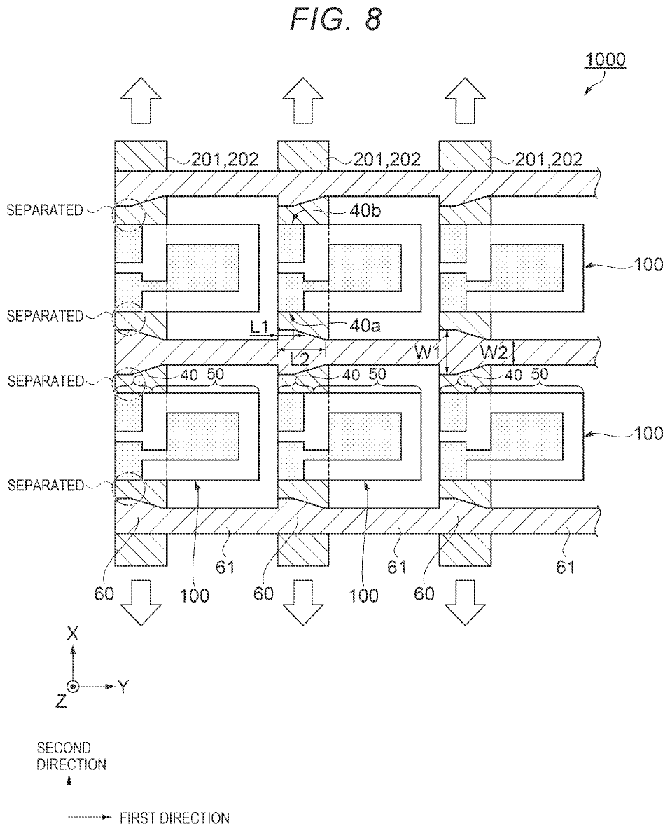

Specifically, as illustrated in FIG. 8, the quartz-crystal wafer 1000, specifically, the film 202 is stretched along the second direction. Accordingly, a coupling portion between the vibrator 100 and the holding portion 60, which are coupled, is pulled and broken. As a result, the coupling portions are separated, and the plurality of vibrators 100 are simultaneously singulated from each other.

It is preferable that length L1 of portions of the holding portion 60 in contact with the end portions 40a and 40b of the vibrator 100 in the first direction are smaller than a length L2 of the holding portion 60 in the first direction. Specifically, the holding portion 60 has a tapered shape from a width W1 of the coupling portion of the holding portion 60 to a width W2 of the first coupling portion 61 so that a crack is likely to occur in the coupling portions between the end portions 40a and 40b and the holding portion 60 when the film 202 is stretched in the second direction. Accordingly, the coupling portion is likely to break, and it is possible to easily singulate the vibrators 100.

The adhesive 201 adhered to the support portion 40 and the holding portion 60 may be attached only to a portion in contact with the support portion 40 and the holding portion 60, or may be attached to the entire surface of the film 202.

As described above, the method for manufacturing the vibrator 100 according to the embodiment includes: the preparation process of preparing the quartz-crystal wafer 1000 including the vibrator 100 and the holding portion 60, the vibrator 100 including the support portion 40 and the vibration part 50 arranged side by side along the first direction, the holding portion 60 being coupled to the one end portion 40a of the support portion 40 in the second direction intersecting the first direction; the adhering process of fixing at least the support portion 40 and the holding portion 60 of the quartz-crystal wafer 1000 to the film 202 via the adhesive 201; and the singulation process of stretching the film 202 along the second direction, and separating and singulating the vibrator 100 from the holding portion 60.

According to this method, since the vibrator 100 is singulated by stretching the film 202, for example, it is possible to prevent damage to the vibrator 100 and to prevent the vibration characteristics of the vibrator 100 from being affected as compared with a method of singulating the vibrator 100 by pressing a protruding portion against the vibrator 100. In addition, since the support portion 40 and the holding portion 60 of the vibrator 100 are fixed to the film 202 via the adhesive 201, it is possible to prevent scattering of broken debris during singulation. Further, since the adhesive 201 is attached to the support portion 40 and the holding portion 60, it is possible to prevent the adhesive 201 from being attached to the vibration part 50, such as to the excitation electrodes 21 and 22 and affecting the vibration characteristics.

In addition, in the method for manufacturing the vibrator 100 according to the embodiment, the quartz-crystal wafer 1000 preferably includes a plurality of holding portions 60 coupled by the first coupling portions 61 and a plurality of vibrators 100 arranged side by side along the first direction, the plurality of holding portions 60 coupled by the first coupling portion 61 and the plurality of vibrators 100 arranged side by side along the first direction are preferably alternately arranged along the second direction, and the other end portion 40b of the support portions 40 of the vibrator 100 in the second direction is also preferably coupled to the holding portion 60. According to this method, since the plurality of holding portions 60 coupled by the first coupling portion 61 in the first direction and the plurality of vibrators 100 are arranged in the second direction, a larger number of vibrators 100 can be singulated at the same time by stretching the film 202 in the second direction.

In addition, in the method for manufacturing the vibrator 100 according to the embodiment, it is preferable that the length L1 of the holding portion 60 in the first direction in contact with the end portion 40a of the vibrator 100 is smaller than the length L2 of the holding portion 60 in the first direction. According to this method, since the length L1 of the holding portion 60 in contact with the end portion 40a is small, when the film 202 is stretched in the second direction, a crack is likely to occur in a coupled portion, and the coupled portion can be easily broken. Accordingly, it is possible to easily singulate the vibrator 100.

Hereinafter, modifications of the above-described embodiment will be described.

As described above, the present disclosure is not limited to adhering the film 202 to the portion of the vibrator 100 overlapping the support portion 40, and a film 202a may be adhered to the entire surface of a quartz-crystal wafer 1000a.

Specifically, the quartz-crystal wafer 1000a according to a modification illustrated in FIG. 9 has the same configuration as the quartz-crystal wafer 1000 of the above-described embodiment. As a different portion, the entire surface of the quartz-crystal wafer 1000a is fixed to the film 202a via an adhesive 201a. The adhesive 201a may be attached only to the vibrator 100, the holding portion 60, and the first coupling portion 61, or may be attached to the entire surface of the film 202a.

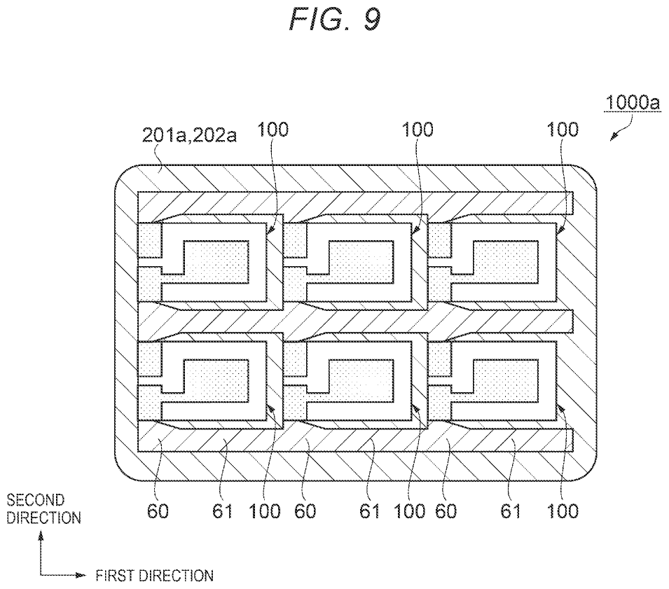

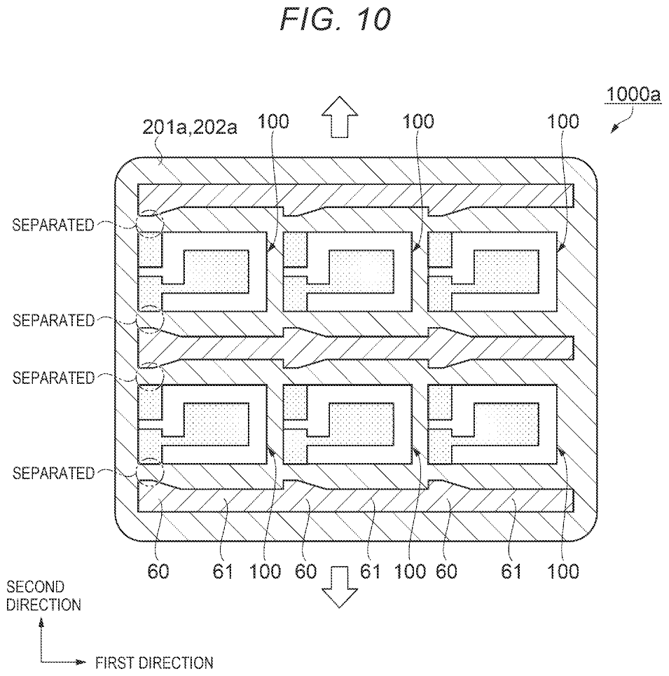

In the method for manufacturing the vibrator 100 on the quartz-crystal wafer 1000a and the film 202a, as illustrated in FIG. 10, the film 202a is stretched along the second direction (singulation process). Accordingly, a coupling portion between the vibrator 100 and the holding portion 60, which are coupled, is pulled and broken. As a result, the coupling portions are separated, and the plurality of vibrators 100 are singulated simultaneously.

After the vibrator 100 is singulated, there is an ashing process for performing frequency adjustment. Therefore, it is preferable that an attaching surface of the film 202a on the quartz-crystal wafer 1000a is set as an upper surface, and the ashing process of the attaching surface is performed simultaneously with the frequency adjustment. Accordingly, the adhesive 201a can be removed, and the adhesive 201a can be prevented from affecting an excitation electrode of the vibration part 50.

As described above, in the method for manufacturing the vibrator 100 according to the modification, in the adhering process, the entire surface of the quartz-crystal wafer 1000a is preferably fixed to the film 202a via the adhesive 201a. According to this method, the entire surface of the quartz-crystal wafer 1000a is fixed to the film 202a. In other words, since the quartz-crystal wafer 1000a is fixed via the adhesive 201a on the film 202a covering the entire surface of the quartz-crystal wafer 1000a, time for aligning the film 202a can be shortened and the film 202a can be easily fixed to the quartz-crystal wafer 1000a. In addition, by attaching the adhesive 201a to the entire surface of the film 202a, it is possible to prevent scattering of broken debris of the holding portion 60 or the like during the singulation.

In addition, it is preferable to provide an ashing process of performing ashing on the surface of the vibrator 100, which is fixed with the adhesive 201a, after the singulation process. According to this method, it is possible to remove the adhesive 201a by subjecting the surface fixed with the adhesive 201a to the ashing process, and it is possible to prevent the vibration characteristics of the vibrator 100 from being affected.

In addition, when the adhesive 201a is an ultraviolet curing type adhesive, it is preferable to provide an ultraviolet irradiation process of irradiating the vibrator 100 with ultraviolet light after the singulation process. According to this method, it is possible to reduce an adhesive force of the adhesive 201a attached to the vibrator 100 by irradiating the vibrator 100 with ultraviolet light, and it is possible to easily handle the vibrator 100.

As described above, instead of singulating the vibrator 100 from the quartz-crystal wafer 1000 having a plurality of vibrators 100 in the first direction and the second direction, the vibrator 100 may be singulated from a quartz-crystal wafer 1000b having one vibrator 100.

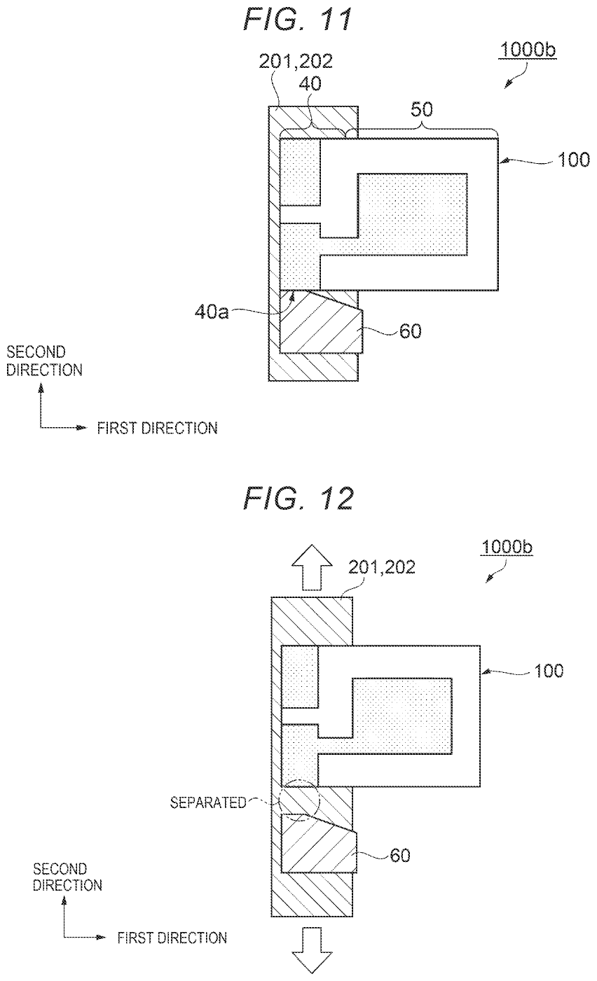

Specifically, as illustrated in FIG. 11, the quartz-crystal wafer 1000b according to a modification includes the vibrator 100 that includes the support portion 40 and the vibration part 50 arranged side by side along the first direction, and the holding portion 60 coupled to one end portion 40a of the support portion 40 in the second direction intersecting the first direction.

In the adhering process, at least the support portion 40 and the holding portion 60 of the quartz-crystal wafer 1000b are fixed to the film 202 via the adhesive 201. In the singulation process, as illustrate in FIG. 12, the film 202 is stretched along the second direction, and the vibrator 100 is singulated by being separated from the holding portion 60. Accordingly, similarly to the above-described embodiment, it is possible to prevent damage to the vibrator 100, and it is possible to prevent the vibration characteristics of the vibrator 100 from being affected. In addition, since the vibrator 100 and the holding portion 60 are fixed to the film 202 via the adhesive 201, it is possible to prevent scattering of broken debris during singulation. In addition, since the adhesive 201 is attached to the support portion 40 and the holding portion 60, it is possible to prevent an occurrence that the adhesive 201 affects the vibration characteristics due to attachment to the vibration part 50.

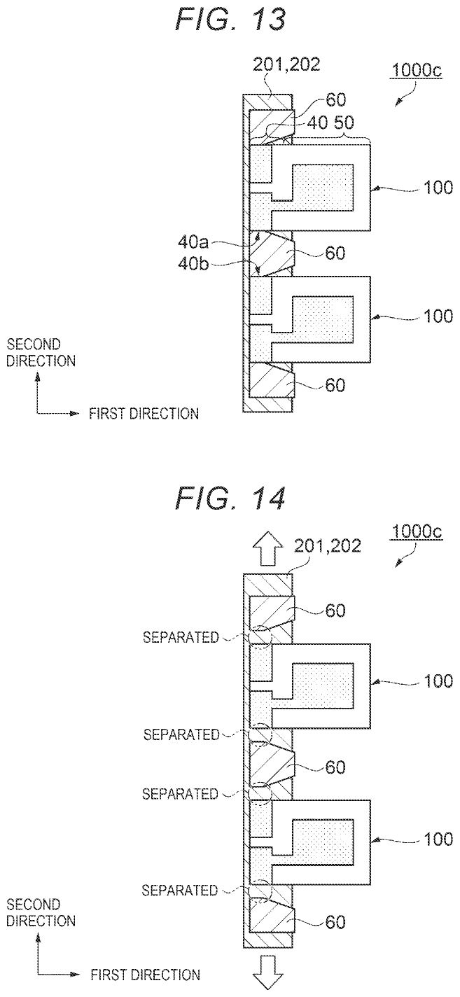

Further, in addition to the configuration of the quartz-crystal wafer 1000b according to the above-described modification, the vibrator 100 may be singulated as illustrated in FIG. 14 from a quartz-crystal wafer 1000c having a configuration in which a plurality of vibrators 100 are arranged side by side in the second direction, that is, a configuration in which two vibrators 100 are arranged side by side in FIG. 13.

Specifically, as illustrated in FIG. 13, the quartz-crystal wafer 1000c according to the modification includes a plurality of vibrators 100 and a plurality of holding portions 60 that are arranged along the second direction, and the other end portion 40b of the support portion 40 of the vibrator 100 in the second direction and the holding portion 60 are coupled. According to this method, since the other end portion 40b of the support portion 40 and the holding portion 60 are coupled to each other, in other words, the plurality of vibrators 100 and the plurality of holding portions 60 are alternately arranged, a large number of vibrators 100 can be singulated simultaneously by stretching the film 202.

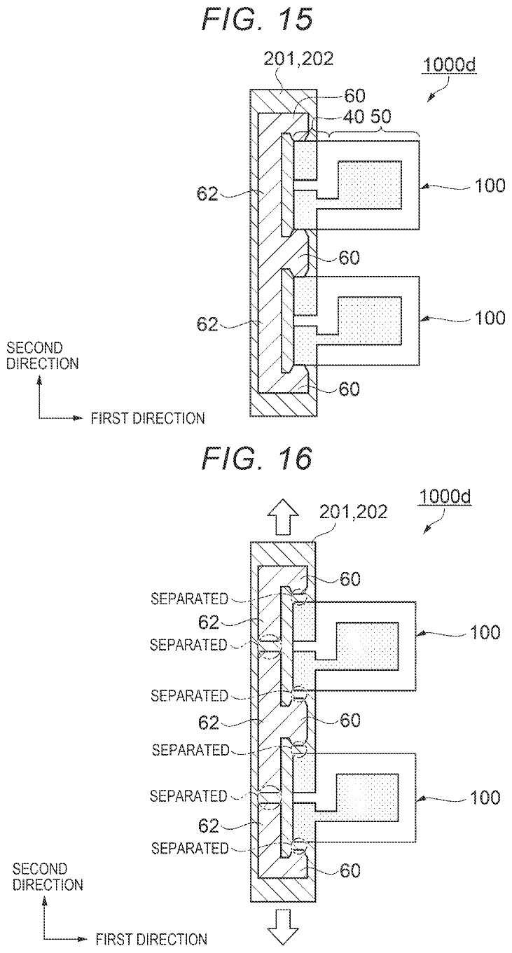

In addition, as illustrated in FIG. 15, a quartz-crystal wafer 1000d according to a modification may further include a second coupling portion 62 that extends along the second direction, is disposed closer to the support portion 40 of the vibrator 100, and is coupled to a plurality of holding portions 60. In the singulation process, as illustrated in FIG. 16, the second coupling portion 62 is broken. According to this method, since the second coupling portion 62 coupled to a plurality of holding portions 60 is provided, strength of the holding portion 60 can be improved, and the quartz-crystal wafer 1000d can be stably handled. In addition, the quartz-crystal wafer 1000d can be stably manufactured before proceeding to the singulation process. When the second coupling portion 62 is provided, the strength of the entire quartz-crystal wafer 1000d can be improved. When the second coupling portion 62 is not provided, the number of vibrators 100 that are singulated from the quartz-crystal wafer 1000d can be increased accordingly.

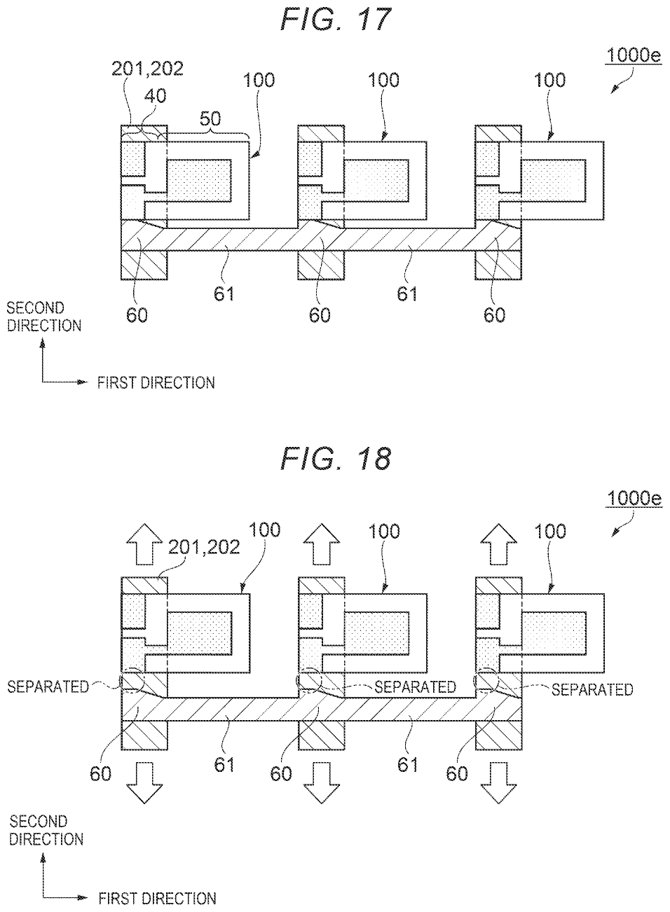

In addition, as illustrated in FIG. 17, a quartz-crystal wafer 1000e according to a modification includes a plurality of vibrators 100 arranged side by side along the first direction, a plurality of holding portions 60 coupled to the plurality of vibrators 100 in one-to-one correspondence, and the first coupling portion 61 coupling the holding portions 60 adjacent to each other in the first direction. In the singulation process, as illustrated in FIG. 18, the film 202 is stretched along the second direction to separate the vibrator 100 from the holding portion 60.

According to this method, since the plurality of vibrators 100 arranged side by side in the first direction are coupled to each other via the first coupling portion 61, a large number of vibrators 100 can be simultaneously singulated by stretching the film 202 in the second direction. In addition, since the plurality of holding portions 60 are coupled by the first coupling portion 61, the strength of the holding portion 60 can be improved, and the quartz-crystal wafer 1000e can be stably handled.

In addition, as described above, a tapered shape for reducing an contact area with the holding portion 60 is set so that a crack is likely to occur in the coupling portions between the end portions 40a and 40b of the vibrator 100 and the holding portion 60, but the present disclosure is not limited thereto and the following may be adopted.

Regarding a thickness of the holding portion 60 in a direction intersecting the first direction and the second direction, it is preferable that a portion coupled to the support portion 40, in other words, the portion coupled to the end portions 40a and 40b of the vibrator 100 is formed to be the thinnest. According to this method, since the portion of the holding portion 60 coupled to the support portion 40 is formed to be thin, when the film 202 is stretched, the vibrator 100 can be easily separated from the thin portion.

Further, it is preferable that a recessed groove or a through hole is formed in a portion of the holding portion 60 that is coupled to the support portion 40. According to this method, since a recessed groove or a through hole is formed in the portion of the holding portion 60 that is coupled to the support portion 40, strength of the portion can be reduced. When the film 202 is stretched, the portion having the reduced strength is likely to break, and the vibrator 100 can be easily singulated.

In addition, it is preferable to provide an energy irradiation process of irradiating the portion of the holding portion 60 coupled to the support portion 40 with an energy ray. The energy ray is, for example, ultraviolet light or an ion beam. According to this method, by performing energy irradiation on the coupled portion of the holding portion 60, the holding portion 60 can be made fragile and can be easily broken. Accordingly, it is possible to easily singulate the vibrator 100.

What is claimed is:

1. A method for manufacturing a vibrator, comprising:
a preparation process of preparing a quartz-crystal wafer including a vibrator and a holding portion, the vibrator including a support portion and a vibration part arranged side by side along a first direction, the holding portion being coupled to one end portion of the support portion in a second direction intersecting the first direction;
an adhering process of fixing at least the support portion and the holding portion of the quartz-crystal wafer to a film via an adhesive; and
a singulation process of stretching the film along the second direction and separating and singulating the vibrator from the holding portion.

2. The method for manufacturing a vibrator according to claim 1, wherein
the quartz-crystal wafer includes
a plurality of the vibrators arranged side by side along the first direction,
a plurality of the holding portions coupled to the plurality of the vibrators in one-to-one correspondence, and
a first coupling portion coupling the holding portions adjacent to each other in the first direction.

3. The method for manufacturing a vibrator according to claim 2, wherein
the quartz-crystal wafer includes a plurality of the holding portions coupled by the first coupling portion and a plurality of the vibrators arranged side by side along the first direction,
the plurality of holding portions coupled by the first coupling portion and the plurality of vibrators arranged side by side along the first direction are alternately arranged along the second direction, and
the other end portion of the support portion of the vibrator in the second direction is also coupled to the holding portion.

4. The method for manufacturing a vibrator according to claim 3, wherein
in the adhering process, an entire surface of the quartz-crystal wafer is fixed to the film via the adhesive.

5. The method for manufacturing a vibrator according to claim 4, further comprising:
an ashing process of performing ashing on a surface of the vibrator, which is fixed with the adhesive, after the singulation process.

6. The method for manufacturing a vibrator according to claim 1, wherein
the quartz-crystal wafer includes a plurality of the vibrators and a plurality of the holding portions that are arranged along the second direction, and
the other end portion of the support portion of the vibrator in the second direction and the holding portion are coupled.

7. The method for manufacturing a vibrator according to claim 6, wherein
the quartz-crystal wafer further includes a second coupling portion extending along the second direction, disposed closer to the support portion of the vibrator, and coupled to the plurality of holding portion, and
in the singulation process, the second coupling portion is broken.

8. The method for manufacturing a vibrator according to claim 1, wherein
the adhesive is an ultraviolet curing type adhesive, and
an ultraviolet irradiation process of irradiating the vibrator with ultraviolet light after the singulation process is provided.

9. The method for manufacturing a vibrator according to claim 1, wherein
a length of a portion of the holding portion in contact with the end portion of vibrator in the first direction is smaller than a length of the holding portion in the first direction.

10. The method for manufacturing a vibrator according to claim 1, wherein
regarding a thickness of the holding portion in a direction intersecting the first direction and the second direction, a portion coupled to the support portion is formed to be the thinnest.

11. The method for manufacturing a vibrator according to claim 1, wherein
a recessed groove or a through hole is formed in a portion of the holding portion that is coupled to the support portion.

12. The method for manufacturing a vibrator according to claim 1, further comprising:
an energy irradiation process of irradiating a portion of the holding portion, which is coupled to the support portion, with an energy ray.
